(19) United States
(12) Patent Application Publication
(10) Pub. No.: US 2015/0255323 A1
(43) Pub. Date: Sep. 10, 2015

(54) SEMICONDUCTOR DEVICE AND METHOD OF MANUFACTURING SAME

(71) Applicant: Kabushiki KaishaToshiba, Minato-ku (JP)

(72) Inventor: Yuko JIMMA, Yokkaichi-shi (JP)

(73) Assignee: Kabushiki KaishaToshiba, Minato-ku (JP)

(21) Appl. No.: 14/323,168

(22) Filed: Jul. 3, 2014

Related U.S. Application Data
(60) Provisional application No. 61/949,770, filed on Mar. 7, 2014.

(51) Int. Cl. H01L 21/764; H01L 29/24; H01L 29/66; H01L 27/115

(52) U.S. Cl. CPC H01L 21/764; H01L 27/11524; H01L 29/24; H01L 29/66825

(57) ABSTRACT

In one embodiment, a semiconductor device includes a semiconductor substrate including device regions which extend in a first direction and are adjacent to one another in a second direction perpendicular to the first direction, and isolation regions disposed between the device regions. The device further includes a gate insulator disposed on a device region, a charge storing layer disposed on the gate insulator, and a hafnium containing film disposed on the charge storing layer, a width of the hafnium containing film in the second direction being larger than a width of at least one of a lower face of the charge storing layer, the gate insulator, and an upper face of the device region in the second direction.

### CROSS REFERENCE TO RELATED APPLICATION

This application is based upon and claims the benefit of priority from the prior U.S. Provisional Patent Application No. 61/949,770 filed on Mar. 7, 2014, the entire contents of which are incorporated herein by reference.

### FIELD

Embodiments described herein relate to a semiconductor device and a method of manufacturing the same.

### BACKGROUND

As a distance between memory cells of a semiconductor memory becomes shorter due to a size reduction of the semiconductor memory, it becomes more difficult to realize isolation between the memory cells by an insulator. Therefore, the isolation between the memory cells is often realized by an air gap. The air gap is typically formed by forming an insulator in an isolation trench on a semiconductor substrate and etching this insulator. In this case, the problem is that the semiconductor substrate can possibly suffer damage due to the etching.

### BRIEF DESCRIPTION OF THE DRAWINGS

FIGS. 1A and 1B are cross-sectional views illustrating a structure of a semiconductor device of a first embodiment;

FIGS. 2A to 6B are cross-sectional views illustrating a method of manufacturing the semiconductor device of the first embodiment; and

FIGS. 7A to 7C are cross-sectional views illustrating structures of semiconductor devices of first to third modifications of the first embodiment.

### DETAILED DESCRIPTION

Embodiments will now be explained with reference to the accompanying drawings.

In one embodiment, a semiconductor device includes a semiconductor substrate including device regions which extend in a first direction and are adjacent to one another in a second direction perpendicular to the first direction, and isolation regions disposed between the device regions. The device further includes a gate insulator disposed on a device region, a charge storing layer disposed on the gate insulator, and a hafnium containing film disposed on the charge storing layer, a width of the hafnium containing film in the second direction being larger than a width of at least one of a lower face of the charge storing layer, the gate insulator, and an upper face of the device region in the second direction.

### First Embodiment

(1) Structure of Semiconductor Device of First Embodiment

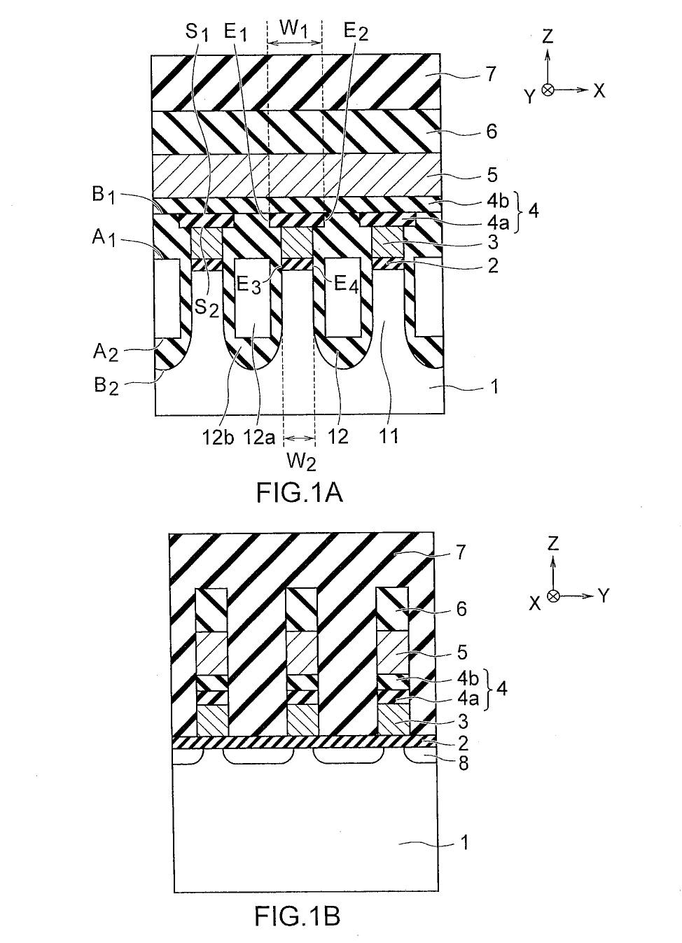

FIGS. 1A and 1B are cross-sectional views illustrating a structure of a semiconductor device of a first embodiment. The device of the present embodiment is a semiconductor memory such as an NAND memory. FIG. 1A illustrates an active area (AA) cross section of the semiconductor memory, and FIG. 1B illustrates a gate conductor (GC) cross section of the semiconductor memory.

The semiconductor device of the present embodiment includes a semiconductor substrate 1, gate insulators 2, charge storing layers 3, intergate insulators 4, control electrode layers 5, mask layers 6, an inter layer dielectric 7 and diffusion regions 8.

An example of the semiconductor substrate 1 is a silicon substrate. FIGS. 1A and 1B illustrate an X-direction and a Y-direction which are parallel to a surface of the semiconductor substrate 1 and are perpendicular to each other, and a Z-direction which is perpendicular to the surface of the semiconductor substrate 1. The Y-direction is an example of a first direction, and the X-direction is an example of a second direction. In this specification, the +Z-direction is regarded as the upward direction, and the −Z-direction is regarded as the downward direction. For example, the positional relation of the semiconductor substrate 1 and the inter layer dielectric 7 is represented as that the inter layer dielectric 7 is positioned above the semiconductor substrate 1.

The semiconductor substrate 1 includes a plurality of device regions 11. The device regions 11 extend in the Y-direction and are adjacent to one another in the X-direction. The semiconductor device of the present embodiment further includes a plurality of isolation regions 12 formed between the device regions 11. Each isolation region 12 includes an air gap 12a, and an isolation insulator 12b having a shape which encloses the air gap 12a. An example of the isolation insulator 12b is a silicon oxide film.

Hereafter, a gate insulator 2, a charge storing layer 3, an intergate insulator 4, a control electrode layer 5 and a mask layer 6 are individually described.

The gate insulator 2 is formed on a device region 11 of the semiconductor substrate 1. An example of the gate insulator 2 is an oxide film such as a silicon oxide film.

The charge storing layer 3 is formed on the gate insulator 2. Examples of the charge storing layer 3 are a semiconductor layer such as a polysilicon layer and a nitride film such as a silicon nitride film. The charge storing layer 3 may be a stack film including one or more of polysilicon layers and one or more of silicon nitride films. An example of the charge storing layer 3 is a floating gate of the NAND memory.

The intergate insulator 4 is formed on the charge storing layer 3. The intergate insulator 4 of the present embodiment includes a hafnium silicate film 4a formed on the charge storing layer 3, and a silicon oxide film 4b formed on the hafnium silicate film 4a.

The hafnium silicate film 4a is an insulator containing hafnium, and has a composition represented by Hf_{X}Si_{1-X}O_{Y} where Hf, Si and O respectively represent hafnium, silicon and oxygen. Moreover, X and Y are real numbers that satisfy 0<X<1 and Y>0. The hafnium silicate film 4a is an example of a hafnium containing film. The hafnium silicate film 4a is formed on each device region 11 as similar to the gate insulator 2 and the charge storing layer 3. On the other hand, the silicon oxide film 4b is formed on plural device regions 11 and has a shape extending in the X-direction as similar to the control electrode layer 5 and the mask layer 6.

The control electrode layer 5 is formed on the intergate insulator 4. An example of the control electrode layer 5 is a polysilicon layer. An example of the control electrode layer 5 is a control gate of the NAND memory.

The mask layer 6 is formed on the control electrode layer 5. An example of the mask layer 6 is a silicon oxide film.

The semiconductor device of the present embodiment includes a plurality of memory cells, each of which is formed of the semiconductor substrate 1, the gate insulator 2, the charge storing layer 3, the intergate insulator 4, the control electrode layer 5 and the mask layer 6. The inter layer dielectric 7 is formed on the semiconductor substrate to cover these memory cells. The diffusion regions 8 are formed in the semiconductor substrate 1 such that they electrically connect these memory cells to one another.

(2) Details of Semiconductor Device of First Embodiment

Continuously referring to FIGS. 1A and 1B, details of the semiconductor device of the first embodiment are described.

[W₁ and W₂]

Sign W₁ indicates a width of the hafnium silicate film 4a in the X-direction. Sign W₂ indicates a width of the charge storing layer 3, the gate insulator 2 and the device region 11 in the X-direction. The width W₁ of the hafnium silicate film 4a of the present embodiment is set larger than the width W₂ of the charge storing layer 3, the gate insulator 2 and the device region 11 (W₁>W₂). The difference between the width W₁ and the width W₂ is, for example, 4 to 6 nm.

It is noted that the charge storing layer 3 of the present embodiment has, in some cases, the width W₂ of its upper portion that is different from the width W₂ of its lower portion as mentioned later. In these cases, the width W₁ of the hafnium silicate film 4a of the present embodiment is set larger than at least the width W₂ of the lower face of the charge storing layer 3.

Also, the device region 11 of the present embodiment has, in some cases, the width W₂ of its upper portion that is different from the width W₂ of its lower portion as illustrated in FIG. 1A. In these cases, the width W₁ of the hafnium silicate film 4a of the present embodiment is set larger than at least the width W₂ of the upper face of the device region 11.

[E₁, E₂, E₃ and E₄]

Signs E₁ and E₂ indicate first and second side ends of the hafnium silicate film 4a in the X-direction, respectively. Sings E₃ and E₄ indicate first and second side ends of the gate insulator 2 in the X-direction, respectively. In FIG. 1A, the first side ends E₁ and E₃ are left end portions, and the second side ends E₂ and E₄ are right end portions.

In the present embodiment, the width W₁ is set larger than the width W₂, so that the first and second side ends E₁ and E₂ of the hafnium silicate film 4a protrude toward the isolation regions 12 relative to the first and second side ends E₃ and E₄ of the gate insulator 2, respectively. A protruding amount of the side end E₁ relative to the side end E₃ is, for example, 2 to 3 nm. Similarly, a protruding amount of the side end E₂ relative to the side end E₄ is, for example, 2 to 3 nm.

First and second side ends of the lower face of the charge storing layer 3 in the X-direction, and first and second side ends of the upper face of the device region 11 in the X-direction can also be defined similarly to the first and second side ends E₃ and E₄ of the gate insulator 2. The first side ends are their left end portions, and the second side ends are their right end portions. In the present embodiment, the first and second side ends E₁ and E₂ of the hafnium silicate film 4a protrude toward the isolation regions 12 relative to the first and second side ends of the lower face of the charge storing layer 3 and the upper face of the device region 11, respectively.

[S₁, S₂, A₁, A₂, B₁ and B₂]

Signs S₁ and S₂ indicate an upper face and a lower face of the hafnium silicate film 4a, respectively. Signs A₁ and A₂ indicate an upper end and a lower end of the air gap 12a, respectively. Signs B₁ and B₂ indicate an upper end and a lower end of the isolation insulator 12b, respectively.

The isolation insulator 12b of the present embodiment is not an insulator formed by coating but is an insulator conformally formed. The insulator formed by coating is first formed at a lower position in the isolation trench, and is finally formed at a higher position in the isolation trench. In this case, the air gap 12a tends to be formed at the higher position in the isolation trench. On the other hand, the insulator conformally formed is first formed on a surface of the isolation trench, and is finally formed at a central portion of the isolation trench. In this case, the air gap 12a tends to be formed at the central portion of the isolation trench.

Therefore, the isolation insulator 12b of the present embodiment is formed on the side surface and the bottom surface of the isolation trench, and the air gap 12a of the present embodiment is formed at the central portion of the isolation trench.

Moreover, the width W₁ of the hafnium silicate film 4a of the present embodiment is set larger than the width W₂ of the charge storing layer 3, the gate insulator 2 and the device region 11, so that the side ends E₁ and E₂ of the hafnium silicate film 4a protrude. In such a situation, when the isolation insulator 12b is conformally formed, the opening of the isolation trench is liable to be closed by the isolation insulator 12b at the height of the hafnium silicate film 4a. The reason is that the opening of the isolation trench is narrow at the height of the hafnium silicate film 4a.

Therefore, the isolation insulator 12b of the present embodiment is formed to have a shape which encloses the air gap 12a. For example, the upper end A₁ of the air gap 12a is formed at a lower position than the upper end B₁ of the isolation insulator 12b, and the lower end A₂ of the air gap 12a is formed at a higher position than the lower end B₂ of the isolation insulator 12b.

Moreover, the opening of the isolation trench of the present embodiment is closed by the isolation insulator 12b at the height of the hafnium silicate film 4a in many cases. Therefore, the height of the upper end A₁ of the air gap 12a of the present embodiment is lower than the height of the lower face S₂ of the hafnium silicate film 4a

Furthermore, the height of the upper end B₁ of the isolation insulator 12b of the present embodiment is set to be same as the height of the upper face S₁ of the hafnium silicate film 4a as mentioned later. Therefore, the height of the upper end B₁ of the isolation insulator 12b of the present embodiment is higher than the height of the lower face S₂ of the hafnium silicate film 4a.

As described above, the air gap 12a of the present embodiment is formed by using the protrusions of the side ends E₁ and E₂ of the hafnium silicate film 4a. Examples of a method of forming such protrusions of the hafnium silicate film 4a are mentioned later.

(3) Method of Manufacturing Semiconductor Device of First Embodiment

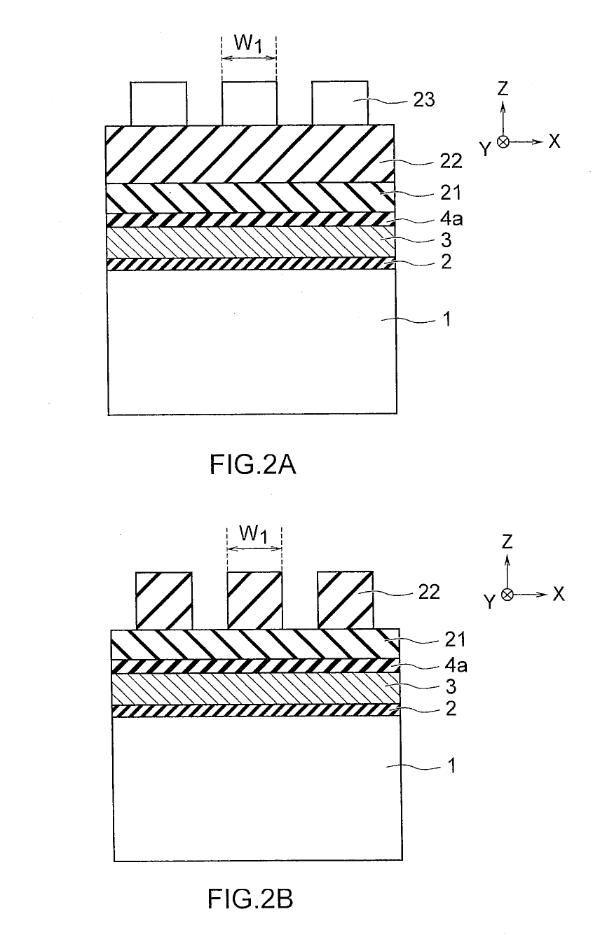

FIGS. 2A to 6B are cross-sectional views illustrating a method of manufacturing the semiconductor device of the first embodiment.

As illustrated in FIG. 2A, the gate insulator 2, the charge storing layer 3, the hafnium silicate film 4a, a first hard mask layer 21, a second hard mask layer 22 and a resist film 23 are formed on the semiconductor substrate 1 in this order. An example of the first hard mask layer 21 is a silicon nitride film. An example of the second hard mask layer 22 is a silicon oxide film.

As illustrated in FIG. 2A, the resist film 23 is then patterned by photolithography. The resist film 23 of the present embodiment is patterned so as to include a plurality of resist patterns which extend in the Y-direction and are adjacent to one another in the X-direction. The width of these resist patterns are set to be approximately W₁.

As illustrated in FIG. 2B, the second hard mask layer 22 is processed by etching using the resist film 23. The resist film 23 is then removed by exposing the semiconductor substrate 1 to an oxygen (O₂) plasma atmosphere.

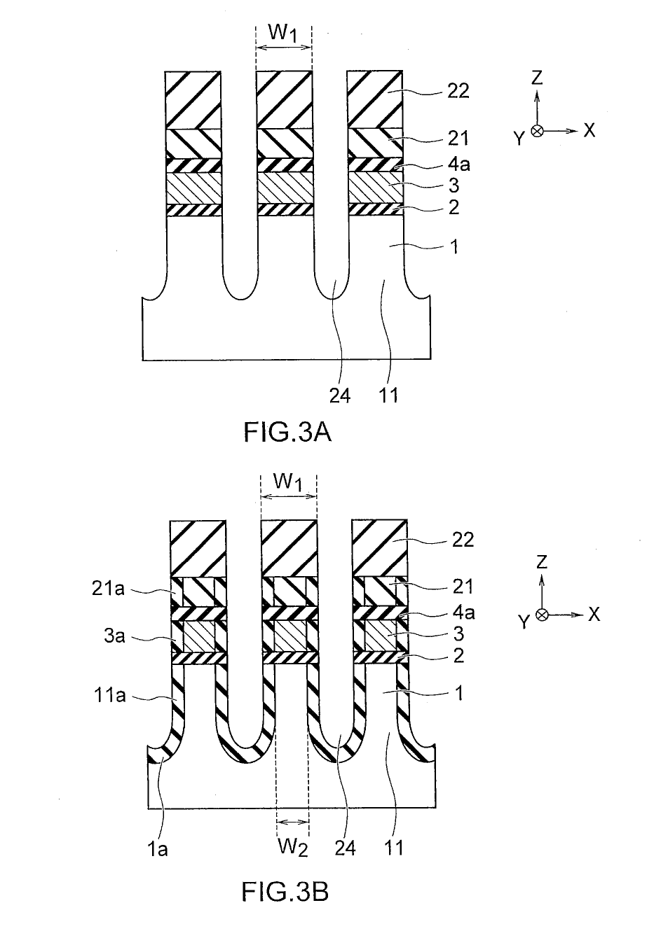

As illustrated in FIG. 3A, the first hard mask layer 21, the hafnium silicate film 4a, the charge storing layer 3, the gate insulator 2 and the semiconductor substrate 1 are processed by etching using the second hard mask layer 22.

As a result, a plurality of isolation trenches 24 which penetrate the hafnium silicate film 4a, the charge storing layer 3 and the gate insulator 2 are formed. The isolation trenches 24 extend in the Y-direction and are adjacent to one another in the X-direction.

Furthermore, the plurality of device regions 11 of the semiconductor substrate 1 are formed between the isolation trenches 24. The device regions 11 are extend in the Y-direction and are adjacent to one another in the X-direction. At the end of the step in FIG. 3A, the width of the device regions 11 is approximately W₁.

As illustrated in FIG. 3B, the semiconductor substrate 1 is then exposed to an oxygen (O₂) plasma atmosphere. As a result, the side faces of the first hard mask layer 21, the charge storing layer 3 and the device regions 11 are oxidized, so that oxide films 21a, 3a and 11a are formed on the side faces of the first hard mask layer 21, the charge storing layer 3 and the device region 11. Similarly, oxide films 1a are formed on other surfaces of the semiconductor substrate 1. The thickness of the oxide film 21a, 3a, 11a and 1a is, for example, 2 to 3 nm.

The first hard mask layer 21, the charge storing layer 3 and the semiconductor substrate 1 of the present embodiment are all formed of materials which can be oxidized. Specifically, the first hard mask layer 21, the charge storing layer 3 and the semiconductor substrate 1 of the present embodiment are a silicon nitride film, a polysilicon layer (or a silicon nitride film) and a silicon substrate, respectively. Therefore, these are oxidized in the step of FIG. 3B.

On the other hand, the second hard mask layer 22, the hafnium silicate film 4a and the gate insulator 2 of the present embodiment are all formed of materials which cannot be oxidized. Specifically, the second hard mask layer 22, the hafnium silicate film 4a and the gate insulator 2 of the present embodiment are a silicon oxide film, a Hf_{X}Si_{1-X}O_{Y} film and a silicon oxide film (gate oxide film), respectively. Therefore, these are not oxidized in the step of FIG. 3B.

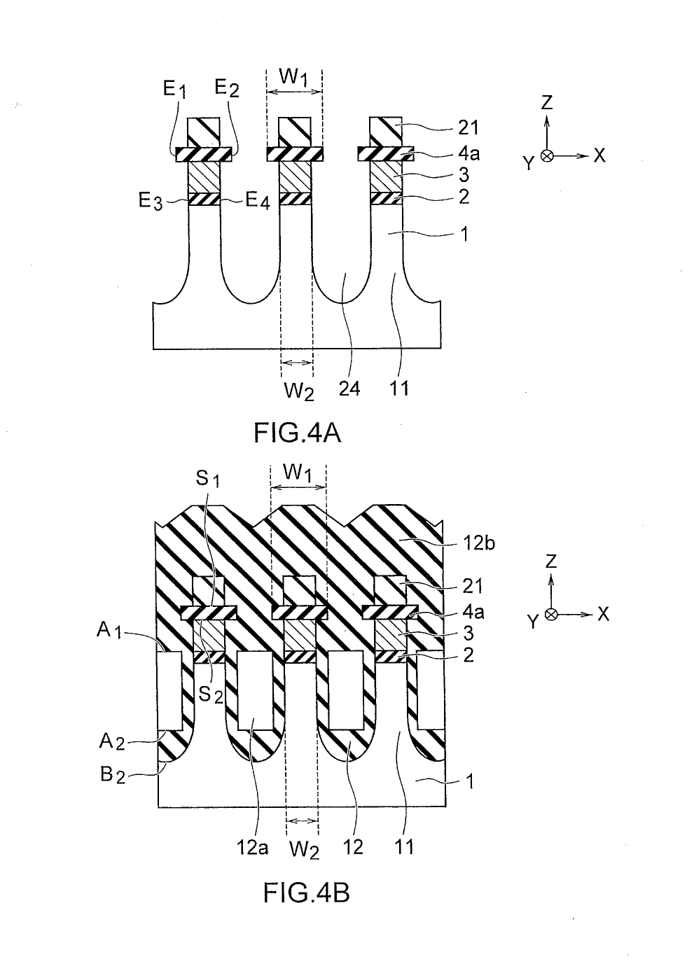

As illustrated in FIG. 4A, the oxide films 21a, 3a, 11a and 1a are removed by wet etching.

At this time, since the second hard mask layer 22 is a silicon oxide film, the second hard mask layer 22 is also removed by the wet etching. Similarly, since the gate insulator 2 is a silicon oxide film, portions of the gate insulator 2 are also removed by the wet etching. Specifically, the gate insulator 2 is removed by the wet etching by a thickness approximately same as those of the oxide films 21a, 3a, 11a and 1a. As a result, the width of the first hard mask layer 21, the charge storing layer 3, the gate insulator 2 and the device region 11 in the X-direction decrease down to W₂ on each device region 11.

On the other hand, the hafnium silicate film 4a has strong resistivity with respect to wet etching. Therefore, the hafnium silicate film 4a is hardly removed by the wet etching in FIG. 4A. As a result, the width of the hafnium silicate film 4a is maintained to be W₁ on each device region 11.

In this way, the width W₁ of the hafnium silicate film 4a becomes larger than the width W₂ of the lower face of the charge storing layer 3, the gate insulator 2, and the upper face of the device region 11.

Furthermore, the first and second side ends (E₁ and E₂) of the hafnium silicate film 4a protrude toward the isolation regions 12 relative to the first and second side ends (E₃, E₄ and the like) of the lower face of the charge storing layer 3, the gate insulator 2, and the upper face of the device region 11, respectively.

As illustrated in FIG. 4B, an isolation insulator 12b is then conformally formed on the whole surface of the semiconductor substrate 1. As a result, the openings of the isolation trenches 24 are closed by the isolation insulator 12b at the height of the hafnium silicate film 4a to form air gaps 12a in the isolation trenches 24. Moreover, the isolation insulator 12b is formed to have a shape which encloses the air gaps 12a. Furthermore, the height of the upper end A₁ of each air gap 12a becomes lower than the height of the lower face S₂ of the hafnium silicate film 4a.

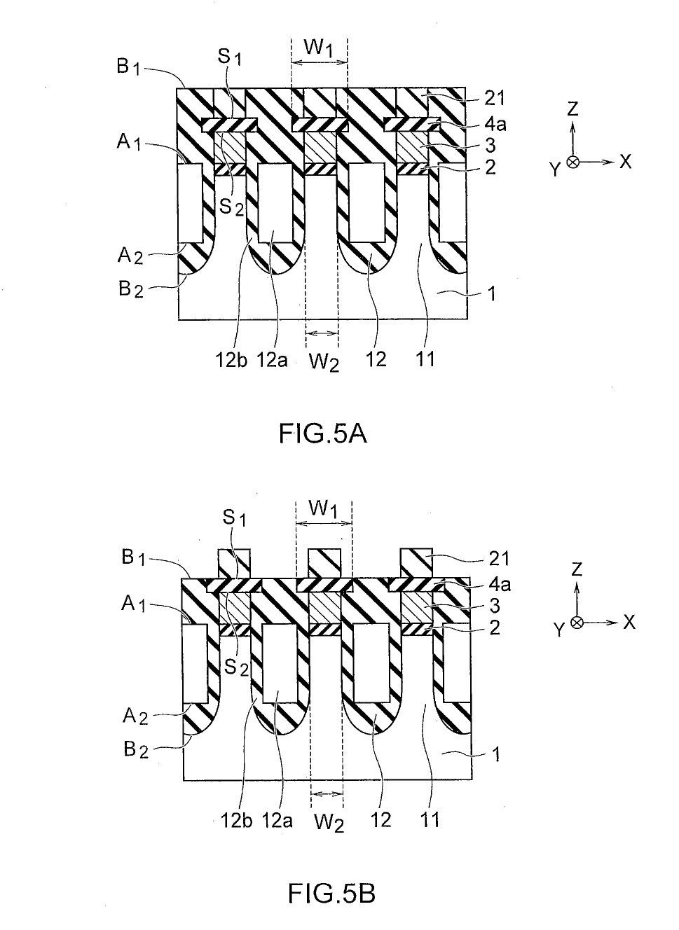

As illustrated in FIG. 5A, the surface of the isolation insulator 12b is planarized by chemical mechanical polishing (CMP). As a result, the plurality of isolation regions 12 including the air gaps 12a and the isolation insulators 12b are formed in the isolation trenches 24. Furthermore, the height of the upper end (upper face) B₁ of each isolation insulator 12b decreases down to the height of the upper face of the first hard mask layer 21.

As illustrated in FIG. 5B, the height of the upper end B₁ of each isolation insulator 12b is reduced down to the height of the upper face S₁ of the hafnium silicate film 4a by etching back the isolation insulators 12b.

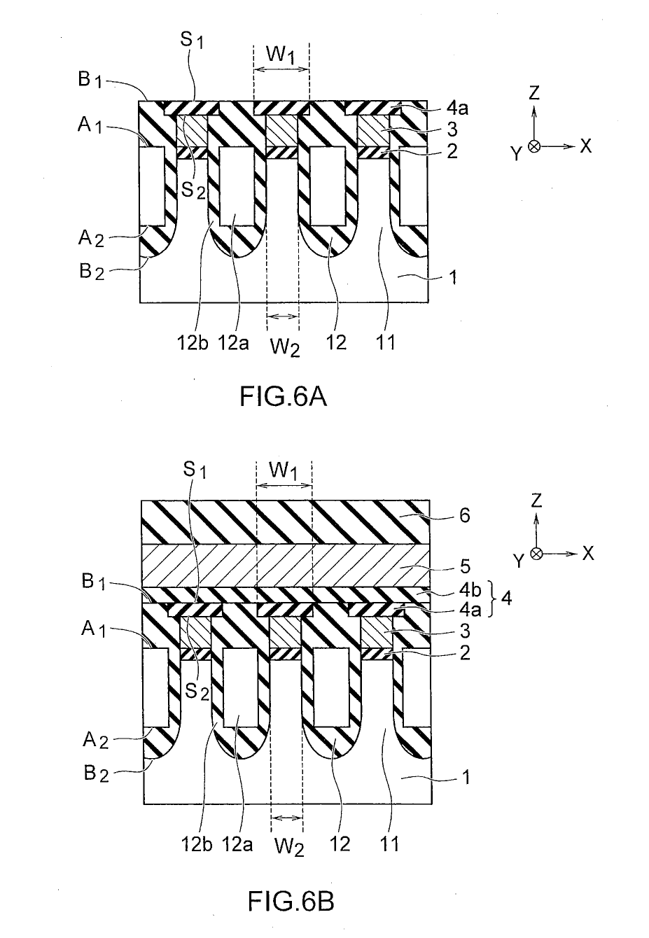

As illustrated in FIG. 6A, the first hard mask layer 21 is then removed by wet etching.

As illustrated in FIG. 6B, the silicon oxide film 4b, the control electrode layer 5 and the mask layer 6 are formed on the whole surface of the semiconductor substrate 1 in this order. As a result, the intergate insulator 4 including the hafnium silicate film 4a and the silicon oxide film 4b is formed.

After that, a gate process of the gate insulator 2, the charge storing layer 3, the intergate insulator 4, the control electrode layer 5 and the mask layer 6 is performed, the diffusion regions 8 are formed in the semiconductor substrate 1, and the inter layer dielectric 7 is formed on the semiconductor substrate 1 (refer to FIGS. 1A and 1B). Furthermore, various inter layer dielectrics, interconnect layers, plug layers and the like are formed on the semiconductor substrate 1. In this way, the semiconductor device of the present embodiment is manufactured.

(4) Modifications of First Embodiment

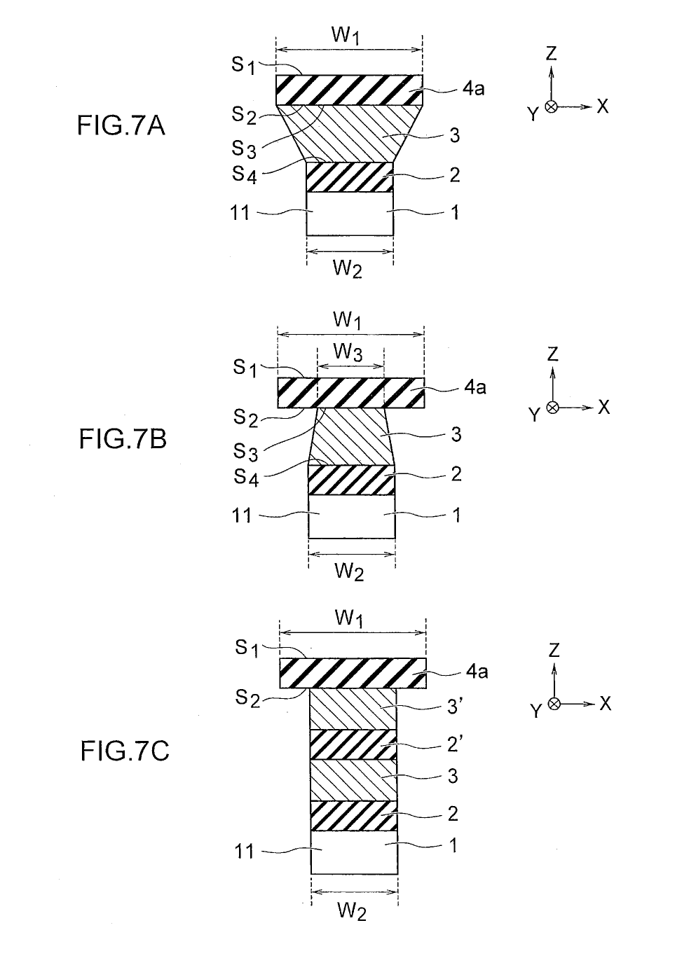

FIGS. 7A to 7C are cross-sectional views illustrating structures of semiconductor devices of first to third modifications of the first embodiment. Each of FIGS. 7A to 7C illustrates the semiconductor substrate 1, the gate insulator 2, the charge storing layer 3, the hafnium silicate film 4a and the device region 11 of each modification.

As exemplarily illustrated in FIGS. 7A and 7B, the width of the charge storing layer 3 of the present embodiment in the X-direction may be uneven. The charge storing layer 3 as in FIG. 7A or 7B can be formed depending on the conditions of the oxidation in FIG. 3B and the conditions of the wet etching in FIG. 4A.

In FIG. 7A, the width of the upper face S₃ of the charge storing layer 3 in the X-direction is set larger than the width of the lower face S₄ of the charge storing layer 3 in the X-direction. Specifically, the width of the lower face S₄ of the charge storing layer 3 is set to be W₂, and the width of the upper face S₃ of the charge storing layer 3 is set to be W₁.

In FIG. 7B, the width of the upper face S₃ of the charge storing layer 3 in the X-direction is set smaller than the width of the lower face S₄ of the charge storing layer 3 in the X-direction. Specifically, the width of the lower face S₄ of the charge storing layer 3 is set to be W₂, and the width of the upper face S₃ of the charge storing layer 3 is set to be W₃ (W₃<W₂).

As exemplarily illustrated in FIG. 7C, the semiconductor device of the present embodiment may include a second gate insulator 2′ and a second charge storing layer 3′ between the device region 11 and the hafnium containing film 4a. Examples of a shape and a material of the second gate insulator 2′ are similar to those of the gate insulator (first gate insulator) 2. Examples of a shape and a material of the second charge storing layer 3′ are similar to those of the charge storing layer (first charge storing layer) 3.

In this manner, the semiconductor device in FIG. 7C includes two gate insulators 2 and 2′ and two charge storing layers 3 and 3′ which are alternately stacked on the device region 11. Similarly, the semiconductor device of the present embodiment may include three or more gate insulators and three or more charge storing layers which are alternately stacked on the device region 11.

As described above, the width W₁ of the hafnium silicate film 4a of the present embodiment is set larger than the width W₂ of the lower face of the charge storing layer 3, the gate insulator 2, and the upper face of the device region 11.

Accordingly, the present embodiment makes it possible, by conformally forming the isolation insulator 12b in the isolation trenches 24, to form the air gaps 12a and the isolation insulators 12b without giving influence of etching on the semiconductor substrate 1. Therefore, according to the present embodiment, the air gaps 12a can be formed while damage to the semiconductor substrate 1 is suppressed.

Moreover, according to the present embodiment, the air gaps 12a can be formed simultaneously to the formation of the isolation insulator 12b, so that the number of steps for manufacturing the semiconductor device can be reduced.

Furthermore, the present embodiment makes it possible, by setting the width W₁ of the hafnium silicate film 4a larger than the width W₂ of the lower face of the charge storing layer 3, the gate insulator 2, and the upper face of the device region 11, to improve coupling of the memory cells.

The hafnium silicate film 4a of the present embodiment may be replaced by a hafnium containing film other than the hafnium silicate film 4a as long as the hafnium containing film is not oxidized in the step of FIG. 3B and is hardly removed in the step of FIG. 4A. Such a hafnium containing film may be an insulating layer that functions as a portion of the intergate insulator 4 or an electrode layer that functions as a portion of the charge storing layer 3.

In the present embodiment, as long as the air gaps 12a can be formed simultaneously to the formation of the isolation insulator 12b, it is not necessary to set the width W₁ of the hafnium silicate film 4a larger than all of the width of the lower face of the charge storing layer 3, the width of the gate insulator 2, and the width of the upper face of the device region 11. In this case, it is sufficient to set the width W₁ of the hafnium silicate film 4a of the present embodiment larger than a width of at least one of the lower face of the charge storing layer 3, the gate insulator 2, and the upper face of the device region 11. For example, when the gate insulator 2 is formed of a material which is hardly removed in the step of FIG. 4A, the width W₁ of the hafnium silicate film 4a can be same as the width of the gate insulator 2.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a semiconductor substrate including device regions which extend in a first direction and are adjacent to one another in a second direction perpendicular to the first direction;
isolation regions disposed between the device regions;
a gate insulator disposed on a device region;
a charge storing layer disposed on the gate insulator; and
a hafnium containing film disposed on the charge storing layer, a width of the hafnium containing film in the second direction being larger than a width of at least one of a lower face of the charge storing layer, the gate insulator, and an upper face of the device region in the second direction.

2. The device of claim 1, wherein the hafnium containing film is a hafnium silicate film.

3. The device of claim 1, wherein first and second side ends of the hafnium containing film in the second direction respectively protrude toward the isolation regions relative to first and second side ends of at least one of the lower face of the charge storing layer, the gate insulator, and the upper face of the device region in the second direction.

4. The device of claim 1, wherein each isolation region includes an air gap.

5. The device of claim 4, wherein a height of an upper end of the air gap is lower than a height of a lower face of the hafnium containing film.

6. The device of claim 4, wherein each isolation region further includes an isolation insulator having a shape which encloses the air gap.

7. The device of claim 6, wherein a height of an upper end of the isolation insulator is higher than a height of a lower face of the hafnium containing film.

8. The device of claim 1, wherein a width of an upper face of the charge storing layer in the second direction is larger than a width of the lower face of the charge storing layer in the second direction.

9. The device of claim 1, wherein a width of an upper face of the charge storing layer in the second direction is smaller than a width of the lower face of the charge storing layer in the second direction.

10. The device of claim 1, further comprising a second gate insulator and a second charge storing layer which are disposed between the device region and the hafnium containing film.

11. A method of manufacturing a semiconductor device, comprising:
forming a gate insulator on a semiconductor substrate;
forming a charge storing layer on the gate insulator;
forming a hafnium containing film on the charge storing layer;
forming isolation trenches which extend in a first direction and are adjacent to one another in a second direction perpendicular to the first direction such that the isolation trenches penetrate the hafnium containing film, the charge storing layer and the gate insulator so as to form device regions of the semiconductor substrate between the isolation trenches;
oxidizing side faces of the charge storing layer and a device region to form an oxide film on the side faces of the charge storing layer and the device region; and
removing the oxide film to make a width of the hafnium containing film in the second direction larger than a width of at least one of a lower face of the charge storing layer, the gate insulator, and an upper face of the device region in the second direction.

12. The method of claim 11, wherein the hafnium containing film is a hafnium silicate film.

13. The method of claim 11, wherein the oxide film is removed such that first and second side ends of the hafnium containing film in the second direction respectively protrude toward the isolation regions relative to first and second side ends of at least one of the lower face of the charge storing layer, the gate insulator, and the upper face of the device region in the second direction.

14. The method of claim 11, wherein the oxide film is formed by using oxygen plasma.

15. The method of claim 11, wherein
the gate insulator is a gate oxide film, and
the oxide film and a portion of the gate oxide film is removed to make the width of the hafnium containing film in the second direction larger than the width of at least one of the lower face of the charge storing layer, the gate insulator, and the upper face of the device region in the second direction.

16. The method of claim 11, wherein the charge storing layer includes at least one of a semiconductor layer and a nitride film.

17. The method of claim 11, further comprising forming an isolation insulator in each isolation trench such that an air gap is formed in each isolation trench.

18. The method of claim 17, wherein the isolation insulator is formed such that a height of an upper end of the air gap is lower than a height of a lower face of the hafnium containing film.

19. The method of claim 17, wherein the isolation insulator is formed to have a shape which encloses the air gap.

20. The method of claim 19, wherein a height of an upper end of the isolation insulator is set higher than a height of a lower face of the hafnium containing film.
